(19) United States
(12) Patent Application Publication
(10) Pub. No.: US 2024/0405505 A1
(43) Pub. Date: Dec. 5, 2024

(54) METHOD OF MANUFACTURING EDGE EMITTING LASERS BY CLEAVING A SEMICONDUCTOR WAFER ALONG ONE OR MORE STREETS FORMED ON THE WAFER

(71) Applicant: Applied Optoelectronics, Inc., Sugar Land, TX (US)

(72) Inventors: Dapeng XU, Houston, TX (US); Klaus Alexander ANSELM, Sugar Land, TX (US); Nahid Sultana, Sugar Land, TX (US)

(21) Appl. No.: 18/205,340

(22) Filed: Jun. 2, 2023

(51) Int. Cl. H01S 5/02; H01S 5/028; H01S 5/10; H01S 5/22; H01S 5/40

(52) U.S. Cl. CPC H01S 5/0202; H01S 5/028; H01S 5/1042; H01S 5/22; H01S 5/4031

(57) ABSTRACT

Methods of manufacturing edge-emitting lasers include cleaving a semiconductor wafer along one or more streets formed on the wafer. A street is an extended region formed without dielectric and metal layers and may be formed on the semiconductor wafer, for example, by a selective wet etching process or a dry etching process. Cleaving along the street(s) without dielectric and metal layers achieves cleaved facets, which are substantially free from microstep defects and metal contamination. After cleaving, a dielectric material may be provided on the remaining street portions along the ends of the cleaved facets, for example, by intentional overspray deposition of facet coatings.

### TECHNICAL FIELD

The present disclosure relates to semiconductor manufacturing methods and more particularly, to a method for manufacturing edge emitting lasers by cleaving a semiconductor waver along one or more streets formed on the wafer.

### BACKGROUND INFORMATION

Semiconductor edge-emitting lasers may be used in various applications, such as Lidar, data center and telecommunication applications, where a high-power laser may be advantageous. Semiconductor edge-emitting lasers may include, for example, ridge waveguide (RWG) lasers and buried heterostructure (BH) lasers. Edge-emitting lasers may be manufactured by forming multiple edge-emitting lasers on a single semiconductor wafer and then cleaving the wafer to form individual lasers or laser bars. The cleaved facets define the cavities of the edge-emitting lasers with one of the cleaved facets acting as an output facet. Because the light is emitted from the output facet, the edge-emitting laser will operate most effectively when that output facet is a mirror-like defect-free facet. One challenge with manufacturing such edge-emitting lasers is forming the output facet substantially free from defects and/or contamination. Cleaving is particularly challenging when manufacturing short cavity lasers (e.g., a cavity length less than 300 μm).

One type of mechanical defect that may occur in the output facet of an edge-emitting laser is known as a microstep defect. FIG. 1A shows an image of a cleaved RWG laser 100 with microstep defects 102 on the output facet. One type of contamination that may occur is metallic contamination that occurs when a portion of a top metallic layer (e.g., composed of gold) is inadvertently deposited on the output facet of the laser(s) during the cleaving process. FIG. 1B shows an image of a cleaved BH laser 110 with metallic contamination 112 on the output facet. Burn-in tests may be used during the manufacturing process to identify potentially defective lasers, and both microstep damage from cleaving and metallic contamination from cleaving may significantly impact the burn-in yield and long-term reliability of the lasers.

Accordingly, there is a need for a method of manufacturing edge-emitting lasers, particularly with short laser cavities, which reduces microstep defects and/or metallic contamination caused during the cleaving process.

### SUMMARY

In accordance with one aspect of the present disclosure, a method is provided for manufacturing edge-emitting lasers. The method includes: providing a semiconductor wafer including a plurality of semiconductor layers forming at least one laser cavity, at least one dielectric layer on the semiconductor layers, and at least one metal layer on the dielectric layer, wherein at least one street is formed on the semiconductor wafer without the metal layer and without the dielectric layer; cleaving the semiconductor wafer along the at least one street to form a plurality of edge-emitting lasers having cleaved facets on each side of the at least one laser cavity, wherein at least one of the cleaved facets provides an output facet for emitting light from the at least one laser cavity; and depositing a dielectric material on a remaining portion of the streets along ends of the cleaved facets.

In accordance with another aspect of the present disclosure, an edge-emitting laser is provided. The edge-emitting laser includes a laser cavity formed by a plurality of semiconductor layers and having cleaved facets at opposite sides of the laser cavity. One of the cleaved facets is an output facet. The edge-emitting laser also includes a dielectric layer and a metal layer deposited on a portion of the semiconductor layers. Street portions without the dielectric layer and the metal layer are formed along ends of the cleaved facets. Facet coatings are deposited on the cleaved facets and on the street portions formed along ends of the cleaved facets.

### BRIEF DESCRIPTION OF THE DRAWINGS

These and other features and advantages will be better understood by reading the following detailed description, taken together with the drawings wherein:

FIG. 1A shows a micrograph of a cleaved output facet of a RWG laser including microstep defects on the output facet.

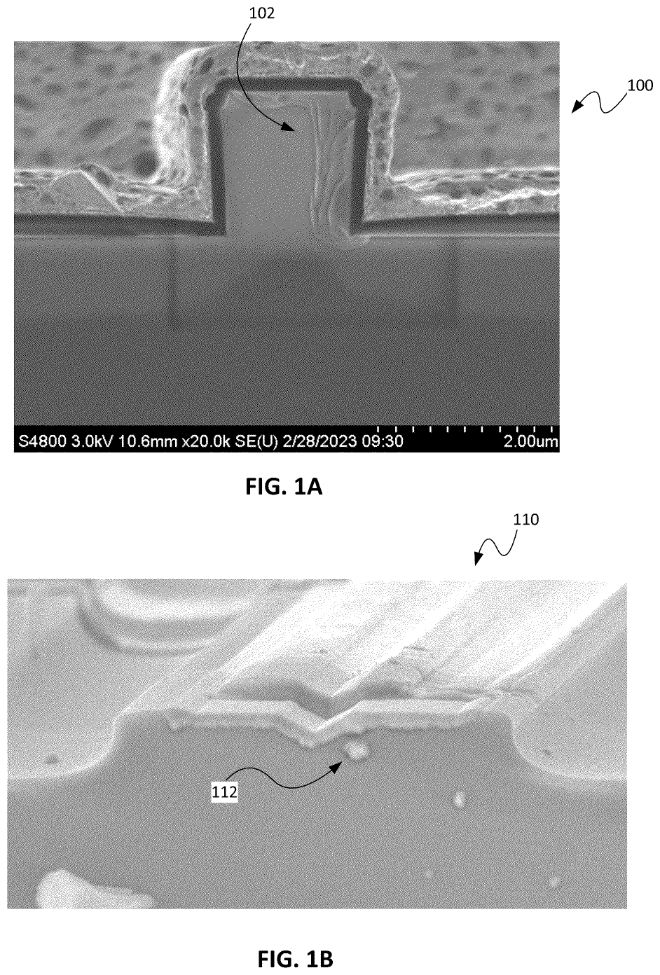

FIG. 1B shows a micrograph of a cleaved output facet of a BH laser including metallic contamination on the output facet.

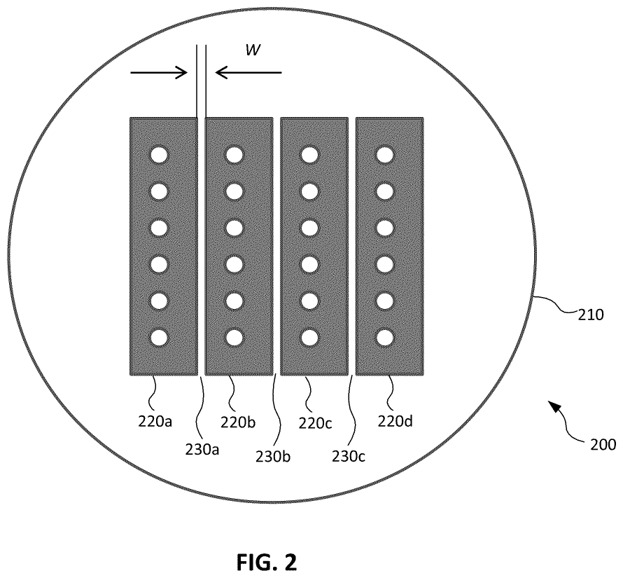

FIG. 2 is a schematic plan view of a semiconductor wafer with streets formed between adjacent laser bar portions, consistent with embodiments of the present disclosure.

FIGS. 3A-3E are schematic side views illustrating a method of forming a semiconductor wafer with a street between adjacent laser bars and then cleaving the semiconductor wafer along the street, consistent with embodiments of the present disclosure.

FIG. 4 is a flow chart illustrating a method for manufacturing edge-emitting lasers by cleaving along streets formed on a semiconductor wafer, consistent with embodiments of the present disclosure.

### DETAILED DESCRIPTION

Methods of manufacturing edge-emitting lasers, consistent with embodiments of the present disclosure, include cleaving a semiconductor wafer along one or more streets formed on the wafer. A street is an extended region formed without dielectric and metal layers and may be formed on the semiconductor wafer, for example, by a selective wet etching process or a dry etching process. Cleaving along the street(s) without dielectric and metal layers achieves cleaved facets, which are substantially free from microstep defects and metal contamination. After cleaving, a dielectric material may be provided on the remaining street portions along the ends of the cleaved facets, for example, by intentional overspray deposition of facet coatings.

The methods described herein recognize that the problem with microstep defects and metallic contamination may be caused by variations in the propagation direction of the cleaving force. This may be a result of metal adhesion, dielectrics layer adhesion, local deposition defects of the metal layer, and/or local deposition defects of the dielectrics layer. One attempt to improve the cleaving process involves scribing the wafer to form a notch and cleaving the wafer along the notch to reduce the cleaving force, for example, as disclosed in U.S. Pat. No. 7,858,493, which is fully incorporated herein by reference. Merely scribing the wafer to form a notch, however, does not solve the above-identified problem with process variations resulting from metal/dielectric adhesion or deposition defects. The method of manufacturing the edge-emitting lasers by cleaving the semiconductor wafer along one or more streets without dielectric and metal layers, consistent with the present disclosure, allows a substantially constant cleaving force and avoids the process variations that cause the microstep defects and metallic contamination.

The methods described herein may be particularly advantageous for manufacturing short cavity edge-emitting lasers having a cavity length less than 300 μm, and more specifically, a cavity length less than 200 μm (e.g., 175 μm). The methods described herein may be used to manufacture ridge waveguide (RWG) lasers, buried heterostructure (BH) lasers, or any other type of edge-emitting lasers.

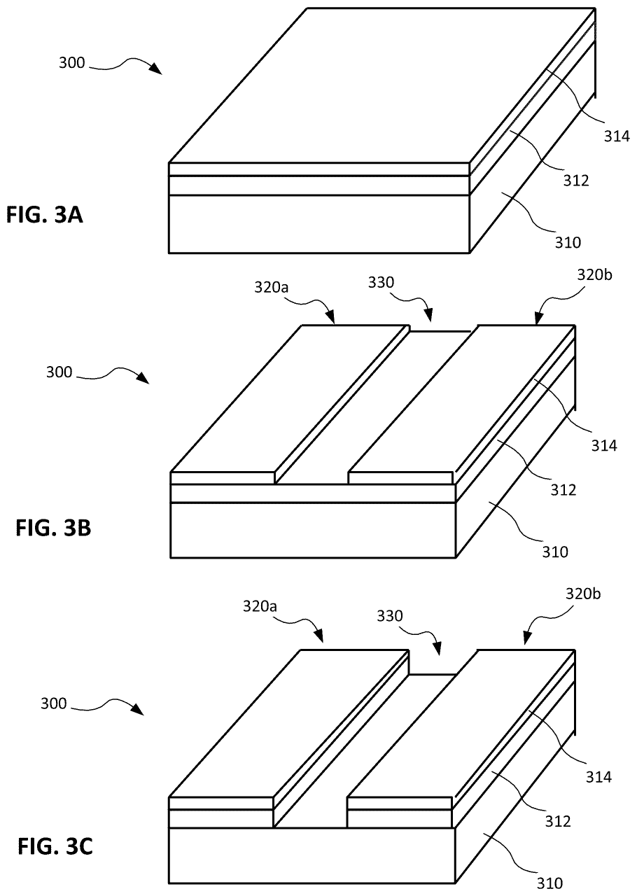

Referring to FIG. 2, an embodiment of a semiconductor wafer 200 used in the method of manufacturing edge-emitting lasers is shown and described. The semiconductor wafer 200 includes a wafer substrate 210 with a plurality of laser bar portions 220a-220d formed on the wafer substrate 210 and separated by streets 230a-230c without dielectric and metal layers. Each of the streets 230a-230c may have a width W in a range of about 2-100 μm.

The semiconductor wafer 200 is cleaved along the streets 230a-230c to separate the laser bar portions 220a-220d, forming separate laser bars that each include a plurality of edge-emitting lasers. Although the illustrated embodiment shows a particular number of laser bar portions 220a-220d and a particular number of lasers included in each of the laser bar portions 220a-220d, other numbers of laser bars and lasers within the laser bars are contemplated and within the scope of the present disclosure.

The semiconductor wafer 210 may be a semiconductor material, such as GaAs or InP crystal, and semiconductor layers (e.g., n-type and p-type layers) may be formed or grown on the semiconductor wafer 210 using known techniques, such as metal organic phase epitaxy (MOVPE) or metal organic chemical vapor deposition (MOCVD). The semiconductor layers may include a type and arrangement of semiconductor lasers known for use in forming edge-emitting lasers, such as ridge waveguide (RWG) lasers or buried heterostructure (BH) lasers. One or more dielectric layers and one or more metal layers are deposited on top of the semiconductor layers using known techniques. The streets 230a-230c are formed without the dielectric layer(s) and the metal layer(s), for example, by first depositing and then removing the dielectric and metal layers, as will be described in greater detail below. The streets 230a-230c may also be formed by selectively depositing or patterning the dielectric and metal layers only on the laser bar portions 220a-220d, for example, using lift off or a shadow mask.

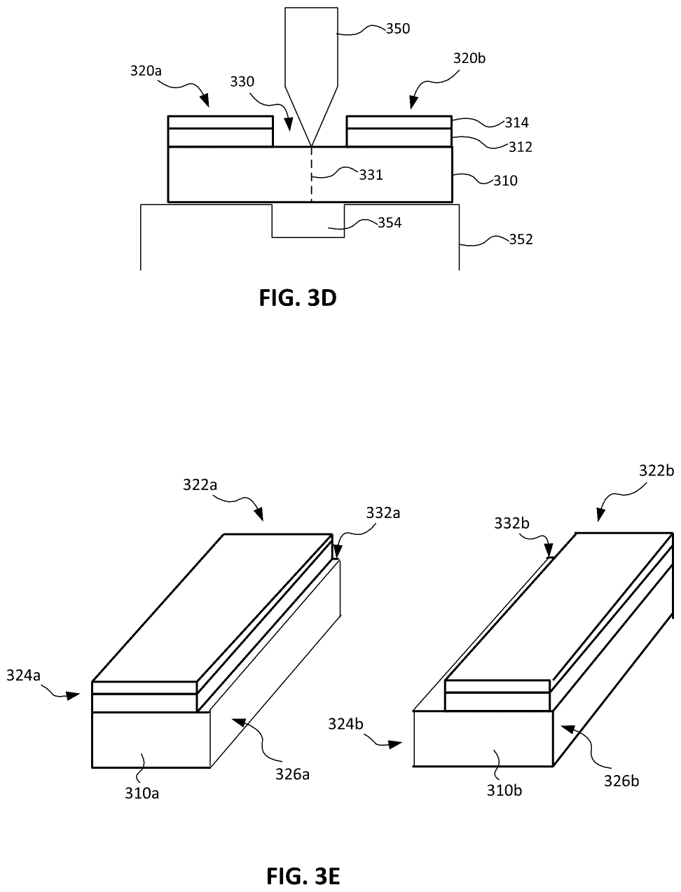

Referred to FIGS. 3A-3E, the formation of a street 330 between laser bar portions 320a, 320b and cleaving along the street 330 is described in greater detail. Although only a portion of the semiconductor wafer 300 is shown with only two laser bar portions 320a, 320b and one street 330 therebetween, the semiconductor wafer 300 may include multiple streets 330 formed between multiple laser bar portions 320a. 320b (e.g., as shown in FIG. 2).

In this example, one or more dielectric layers 312 and one or more metal layers 314 may be formed on top of semiconductor layers 310 on a portion of a semiconductor wafer 300, as shown in FIG. 3A. The semiconductor layers 310, which are shown schematically, may include p-type and n-type layers grown epitaxially and etched to form structures, such as mesa structures, as is generally known in edge-emitting lasers. The metal layer(s) 314 may include a P-contact metallization layer and/or an electroplating layer and the dielectric layer(s) 312 may include dielectric layer(s) deposited between the semiconductor layers and the metal layer(s) 314 to provide current confinement.

A portion of the metal layer(s) 314 may then be removed along the area of the street 330, as shown in FIG. 3B, and a portion of the dielectric layer(s) 312 may be removed along the area of the street 330, as shown in FIG. 3C, thereby forming the street 330 without the dielectric layer(s) and metal layer(s) between laser bar portions 320a, 320b. The metal layer(s) 314 and dielectric layer(s) 312 may be removed, for example, by a known wet or dry etching process.

The remaining semiconductor layers 310 may then be cleaved along the street 330 using known cleaving techniques to separate the laser bar portions 320a, 320b. In one example, as shown in FIG. 3D, a cleaving blade 350 may be used to perform the cleaving with a support member 352 having a cleaving cavity 354 positioned below the cleaving location. Cleaving causes the semiconductor layers 310 to separate along line 331, forming separate laser bars 322a, 322b, as shown in FIG. 3E, with cleaved facets 326a, 324b. For a semiconductor wafer with a plurality of laser bar portions separated by streets (e.g., as shown in FIG. 2), this cleaving process may be repeated along each of the streets to separate multiple laser bars.

Each of the laser bars 322a. 322b may include a plurality of edge-emitting lasers including laser cavities formed by the semiconductor layers 310a. 310b between the facets 324a. 324b, 326a, 326b with one of the facets acting as the output facet 326a, 326b for emitting light. Although the illustrated example shows cleaving in only one location forming cleaved facets 326a, 324b on only one side of the laser bars 322a, 322b, the laser bars are usually cleaved on both sides to form cleaved facets on both sides.

The cleaved facets 326a, 324b may have street portions 332a, 332b remaining along an end of the cleaved facets 326a, 324b where the semiconductor layers 310a, 310b are exposed. To provide passivation at the end of these cleaved facets 326a, 324b and avoid current leakage, the remaining street portions 332a, 332b may be coated with a dielectric material. One method includes an intentional overspray deposition of facet coatings, such as the antireflective (AR) coating on the output facet 326a and the highly reflective (HR) coating on the other facet 324b, which covers the remaining street portions 332a. 332b with the facet coating material. The AR and HR coatings may include known AR and HR coatings for use with edge emitting lasers.

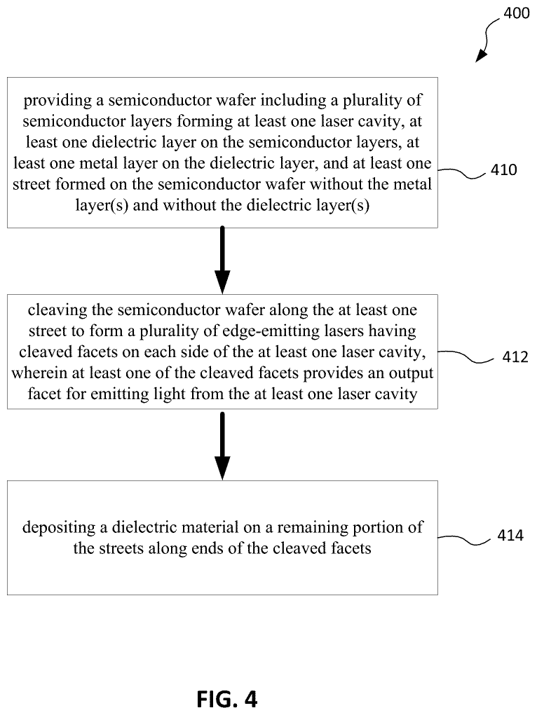

Referring to FIG. 4, a method 400 for manufacturing edge-emitting lasers, consistent with embodiments described above, is described in greater detail. The method 400 generally includes providing 410 a semiconductor wafer including a plurality of semiconductor layers forming at least one laser cavity, at least one dielectric layer on the semiconductor layers, at least one metal layer on the dielectric layer, and at least one street formed on the semiconductor wafer without the metal layer(s) and without the dielectric layer(s). The method 400 also includes cleaving 412 the semiconductor wafer along the at least one street to form a plurality of edge emitting lasers having cleaved facets on each side of a laser cavity. The method 400 further includes depositing 414 a dielectric material on a remaining portion of the street(s) along ends of the cleaved facets.

According to an example of manufacturing RWG laser bars, providing 410 the semiconductor wafer includes depositing semiconductor, dielectric and metal layers and patterning and etching of the layers to form laser bar portions with the RWG lasers. In particular, hetero-epitaxy of the semiconductor layers on a wafer substrate is performed to form the contact and active regions for each of the lasers. Photolithography patterning is then performed followed by etching to a desired depth to define the waveguides and diode mesas of each of the lasers. Deposition of a dielectric material is performed for current confinement to the mesas and etching of the dielectric is performed to open a P-contact region followed by P-contact metallization. An initial street formation may be performed by lifting off at least a portion of metal from the P-contact metallization in the street area, although some of the metal may remain.

Providing 410 the semiconductor wafer also includes substrate thinning followed by N-contact metallization performed on the side where the substrate was removed. Providing 410 the semiconductor wafer may further include depositing a plating seed layer (e.g., Ti/Au) and electroplating on the side with the P-contact metallization. To form streets without the dielectric and metal layers, consistent with the present disclosure, selective wet etching of the streets is performed to remove the electroplating (e.g., the AU/Ti), any remaining metal from the P-contact metallization, and the dielectrics layer in the area of the streets.

In the example of manufacturing RWG laser bars, cleaving 412 the semiconductor wafer includes cleaving along the streets where the metal and dielectric layers were removed by wet etching to separate the laser bar portions into RWG laser bars. In the example method, depositing 414 the dielectric on the remaining portion of the streets includes an intentional overspray deposition of the facet coatings (e.g., AR and HR coatings) on each of the laser facet ends and to cover the remaining streets along the ends of the cleaved facets.

Accordingly, a method for manufacturing edge-emitting lasers, consistent with the present disclosure, forms streets without dielectric and metal layers between the laser portions of a semiconductor wafer to allow a substantially constant cleaving force when separating the laser portions, which avoids the process variations that cause microstep defects and metallic contamination. The method may thus improve the burn-in yield and long-term reliability of the lasers, particularly short cavity edge-emitting lasers such as RWG or BH lasers.

While the principles of the invention have been described herein, it is to be understood by those skilled in the art that this description is made only by way of example and not as a limitation as to the scope of the invention. Other embodiments are contemplated within the scope of the present invention in addition to the exemplary embodiments shown and described herein. Modifications and substitutions by one of ordinary skill in the art are considered to be within the scope of the present invention, which is not to be limited except by the following claims.

What is claimed is:

1. A method for manufacturing edge-emitting lasers, the method comprising:
providing a semiconductor wafer including a plurality of semiconductor layers forming at least one laser cavity, at least one dielectric layer on the semiconductor layers, and at least one metal layer on the dielectric layer, wherein at least one street is formed on the semiconductor wafer without the metal layer and without the dielectric layer;
cleaving the semiconductor wafer along the at least one street to form a plurality of edge-emitting lasers having cleaved facets on each side of the at least one laser cavity, wherein at least one of the cleaved facets provides an output facet for emitting light from the at least one laser cavity; and
depositing a dielectric material on a remaining portion of the streets along ends of the cleaved facets.

2. The method of claim 1 wherein the at least one street is formed between adjacent laser bar portions and cleaving the semiconductor wafer separates the laser bar portions into a plurality of laser bars, and wherein each of the laser bars provides a plurality of edge-emitting lasers.

3. The method of claim 1 wherein providing the semiconductor wafer comprises depositing the semiconductor layers, the at least one dielectric layer and the metal layer and forming the at least one street by wet etching the at least one metal layer and the at least one dielectric layer.

4. The method of claim 1 wherein providing the semiconductor wafer comprises depositing the semiconductor layers, the at least one dielectric layer and the metal layer and forming the at least one street by dry etching the at least one metal layer and the at least one dielectric layer.

5. The method of claim 1 wherein the semiconductor wafer includes a plurality of streets formed without the metal layer and without the dielectric layer.

6. The method of claim 1 wherein depositing the dielectric material includes an intentional overspray deposition of facet coatings on the cleaved facets.

7. The method of claim 6, wherein the facet coatings include an antireflective (AR) coating the output facet.

8. The method of claim 6, wherein the facet coatings include a highly reflective (HR) coating on the cleaved facet opposite the output facet.

9. The method of claim 1 wherein the edge-emitting lasers include ridge waveguide (RWG) lasers.

10. The method of claim 1 wherein the edge-emitting lasers include buried heterostructure (BH) lasers.

11. The method of claim 1 wherein the edge-emitting lasers have a cavity length less than 300 μm.

12. The method of claim 1 wherein the edge-emitting lasers have a cavity length less than 200 μm.

13. An edge-emitting laser comprising:
a laser cavity formed by a plurality of semiconductor layers and having cleaved facets at opposite sides of the laser cavity, wherein one of the cleaved facets is an output facet;
a dielectric layer and a metal layer deposited on a portion of the semiconductor layers, wherein street portions without the dielectric layer and the metal layer are formed along ends of the cleaved facets; and
facet coatings deposited on the cleaved facets and on the street portions formed along ends of the cleaved facets.

14. The edge-emitting laser of claim 13, wherein the facet coatings include an antireflective (AR) coating on the output facet, wherein the AR coating is applied to cover the street portion formed along the end of the output facet.

15. The edge-emitting laser of claim 13, wherein the facet coatings include a highly reflective (HR) coating on the cleaved facet opposite the output facet, wherein the HR coating is applied to cover the street portion formed at the end of the cleaved facet opposite the output facet.

16. The edge-emitting laser of claim 13, wherein the laser cavity has a length less than 300 μm.

17. The edge-emitting laser of claim 13, wherein the laser cavity has a length less than 200 μm.

18. The edge-emitting laser of claim 13, wherein the laser cavity is formed in a laser bar including a plurality of laser cavities.

19. The edge-emitting laser of claim 13, wherein the plurality of semiconductor layers are arranged to form a ridge waveguide (RWG) laser.

20. The edge-emitting laser of claim 13, wherein the plurality of semiconductor layers are arranged to form a buried heterostructure (BH) laser.
